(19) United States
(12) Patent Application Publication
(10) Pub. No.: US 2011/0048517 A1
(43) Pub. Date: Mar. 3, 2011

(54) Multijunction Photovoltaic Cell Fabrication

(75) Inventors: Stephen W. Bedell, Yorktown Heights, NY (US); Norma Sosa Cortes, Yorktown Heights, NY (US); Keith E. Fogel, Yorktown Heights, NY (US); Devendra Sadana, Yorktown Heights, NY (US); Katherine L. Saenger, Yorktown Heights, NY (US); Davood Shahrjerdi, Yorktown Heights, NY (US)

(73) Assignee: INTERNATIONAL BUSINESS MACHINES CORPORATION, Armonk, NY (US)

(21) Appl. No.: 12/713,592

(22) Filed: Feb. 26, 2010

Related U.S. Application Data
(60) Provisional application No. 61/185,247, filed on Jun. 9, 2009.

(51) Int. Cl. H01L 31/101; H01L 31/18

(52) U.S. Cl. 136/255; 438/72; 257/E31.002

(57) ABSTRACT

A method for fabrication of a multijunction photovoltaic (PV) cell includes forming a stack comprising a plurality of junctions on a substrate, each of the plurality of junctions having a respective bandgap, wherein the plurality of junctions are ordered from the junction having the largest bandgap being located on the substrate to the junction having the smallest bandgap being located on top of the stack; forming a metal layer, the metal layer having a tensile stress, on top of the junction having the smallest bandgap; adhering a flexible substrate to the metal layer; and spalling a semiconductor layer from the substrate at a fracture in the substrate, wherein the fracture is formed in response to the tensile stress in the metal layer.

### CROSS-REFERENCE TO RELATED APPLICATION

This application claims the benefit of U.S. Provisional Application No. 61/185,247, filed Jun. 9, 2009. This application is also related to attorney docket numbers YOR920100056US1, YOR920100060US1, FIS920100005US1, and FIS920100006US1, each assigned to International Business Machines Corporation (IBM) and filed on the same day as the instant application, all of which are herein incorporated by reference in their entirety.

### FIELD

This disclosure relates generally to the field of multijunction photovoltaic cell fabrication.

### DESCRIPTION OF RELATED ART

Multijunction III-V based photovoltaic (PV) cells, or tandem cells, are comprised of multiple p-n junctions, each junction comprising a different bandgap material. A multijunction PV cell is relatively efficient, and may absorb a large portion of the solar spectrum. The multijunction cell may be epitaxially grown, with the larger bandgap junctions on top of the lower bandgap junctions. Conversion efficiencies for commercially available 3-junction III-V based photovoltaic structures may be about 30% to 40%. A III-V substrate based triple junction PV cell may be about 200 microns thick range, a major portion of the thickness being contributed by a bottom layer of a substrate, which may also serve as the third junction. The relative thickness of the substrate may cause the substrate layer to be relatively inflexible, rendering the PV cell inflexible.

### SUMMARY

In one aspect, a method for fabrication of a multijunction PV cell includes forming a stack comprising a plurality of junctions on a substrate, each of the plurality of junctions having a respective bandgap, wherein the plurality of junctions are ordered from the junction having the largest bandgap being located on the substrate to the junction having the smallest bandgap being located on top of the stack; forming a metal layer, the metal layer having a tensile stress, on top of the junction having the smallest bandgap; adhering a flexible substrate to the metal layer; and spalling a semiconductor layer from the substrate at a fracture in the substrate, wherein the fracture is formed in response to the tensile stress in the metal layer.

In one aspect, a multijunction PV cell includes at least one semiconductor contact; a stack comprising a plurality of junctions, each of the plurality of junctions having a respective bandgap, wherein the plurality of junctions are ordered from the junction having the largest bandgap being located on the at least one semiconductor contact to the junction having the smallest bandgap being located on top of the stack; a metal layer having a tensile stress located on top of the junction having the smallest bandgap, the metal layer comprising a back contact; and a flexible substrate adhered to the metal layer.

Additional features are realized through the techniques of the present exemplary embodiment. Other embodiments are described in detail herein and are considered a part of what is claimed. For a better understanding of the features of the exemplary embodiment, refer to the description and to the drawings.

### BRIEF DESCRIPTION OF THE SEVERAL VIEWS OF THE DRAWINGS

Referring now to the drawings wherein like elements are numbered alike in the several FIGURES:

FIG. 1 illustrates an embodiment of a method of multijunction PV cell fabrication.

FIG. 2 illustrates an embodiment of a multijunction PV cell.

FIG. 3 illustrates an embodiment of a substrate.

FIG. 4 illustrates an embodiment of a junction of the multijunction cell.

FIG. 5 illustrates an embodiment of a multijunction cell with a stressed metal layer.

FIG. 6 illustrates an embodiment of a multijunction cell with a flexible substrate.

FIG. 7 illustrates an embodiment of a multijunction cell after spalling.

FIG. 8 illustrates an embodiment of a multijunction PV cell.

### DETAILED DESCRIPTION

Embodiments of systems and methods for multijunction PV cell fabrication are provided, with exemplary embodiments being discussed below in detail. Spalling may be used to reduce the thickness of the bottom substrate layer of the PV cell. Reduction in the substrate thickness may lower manufacturing costs, since less substrate material is used in each cell. In addition, since the substrate layer is ordinarily the thickest layer of a PV cell, significantly thinning the substrate may significantly decrease the overall thickness of the cell, thus making the cell more flexible. Spalling may be applied to a single region of a surface of a semiconductor substrate, or to a plurality of localized regions, allowing for selected-area use of the semiconductor substrate. The plurality of localized regions may comprise less than one-hundred percent of the original substrate surface area in some embodiments.

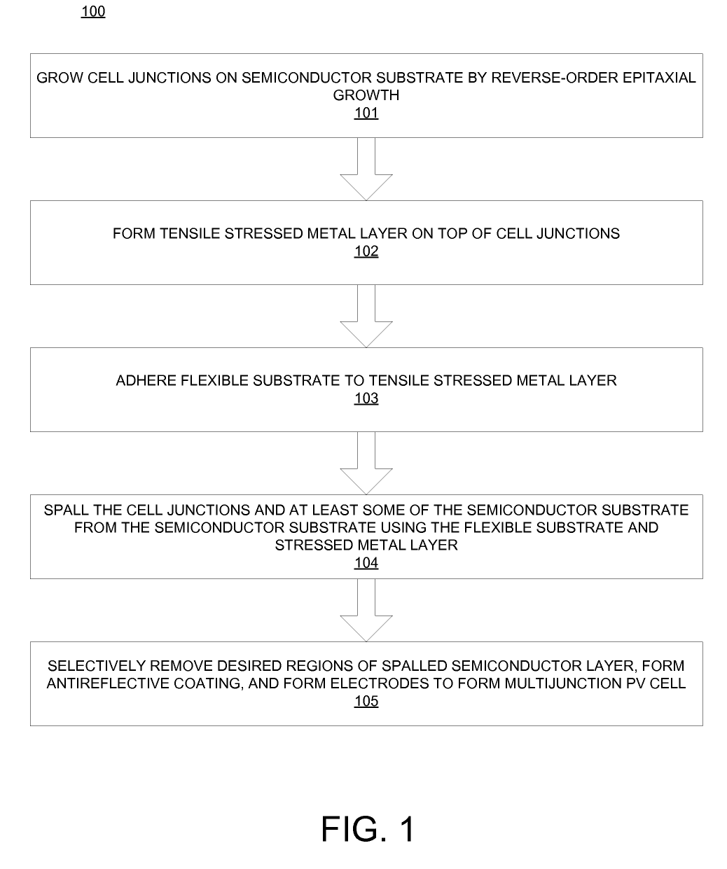

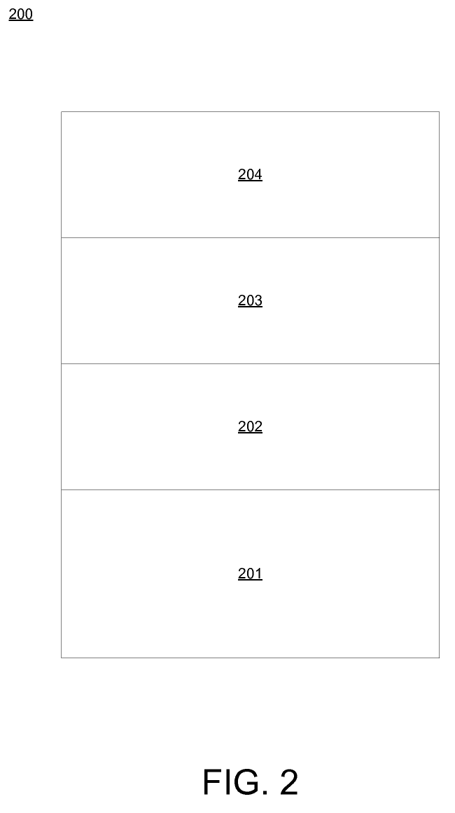

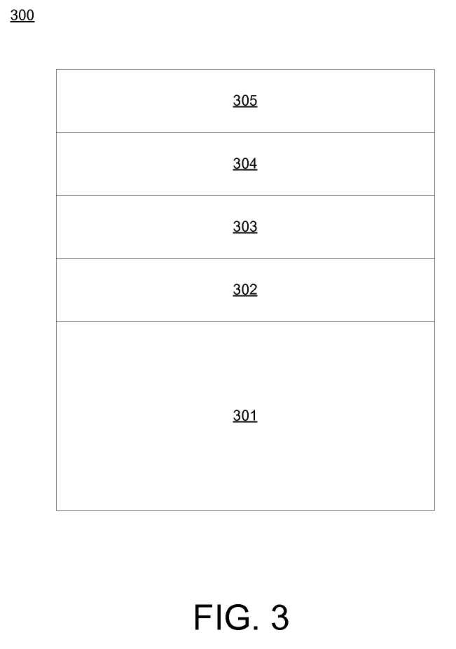

FIG. 1 illustrates an embodiment of a method 100 for fabrication of a multijunction PV cell. FIG. 1 is discussed with reference to FIGS. 2-8. In block 101, a multijunction PV cell 200 as shown in FIG. 2 is formed by reverse-order epitaxial growth. Junction 202 is formed on substrate 201, junction 203 is formed on junction 202, and junction 204 is then formed on junction 203. Substrate 201 may comprise a III-V substrate, such as gallium arsenide (GaAs) or germanium (Ge), in some embodiments. The structure of substrate 201 is discussed further below with respect to FIG. 3. The bandgap of junction 204 is less than the bandgap of junction 203, and the bandgap of junction 203 is less than the bandgap of junction 202. The smallest bandgap p-n junction 204 is grown last, so that when spalling (i.e., layer transfer) is performed (discussed below with respect to block 103), junction 204 may be located adjacent to a back metal contact of the multijunction cell. In some embodiments, junction 204 comprises any appropriate relatively small band-gap p/n material, such as a GaAs-based or Ge-based material; junction 202 comprises any appropriate relatively large bandgap material, such as a GaInP₂ material; and junction 203 comprises any appropriate material having a bandgap between that of junctions 202 and 204. Junctions 202-204 are shown for illustrative purposes only; cell 200 may be grown with any appropriate number of junctions, ordered from the junction having the largest bandgap being located on the substrate 201 to the junction having the smallest bandgap located at the top of the stack.

FIG. 3 illustrates an embodiment of a substrate 300. Embodiments of substrate 201 may comprise the series of layers 301-305 that comprise substrate 300. Substrate 300 comprises semiconductor substrate 301, which may comprise a III-V substrate such as Ge or GaAs, or silicon (Si) in some embodiments. If semiconductor substrate 301 comprises Ge or Si, a seed layer 302 comprising, for example, GaAs or GaInAs may be formed on semiconductor substrate 301. If semiconductor substrate 301 comprises GaAs, seed layer 302 may comprise GaAs. Seed layer 302 may comprise any material having an appropriate lattice parameter that is compatible with junction 202. Etch stop/release layer 303 is grown on seed layer 302. Etch stop/release layer 303 may help to induce a specific depth for formation of fracture 702 during spalling (discussed below with respect to block 104). Second seed layer 304 is grown on etch stop/release layer 303. Second seed layer 304 may comprise the same material as seed layer 302. Spalling (discussed below with respect to block 104) may occur in second seed layer 304. Etch stop layer 305 is grown on second seed layer 304. Etch stop/release layer 303 and etch stop layer 305 may comprise AlAs-based or GaInP in some embodiments. Junction 202 is grown on etch stop layer 305. Substrate 300 is shown for illustrative purposes only; substrate 300 may comprise any appropriate number and type of layers.

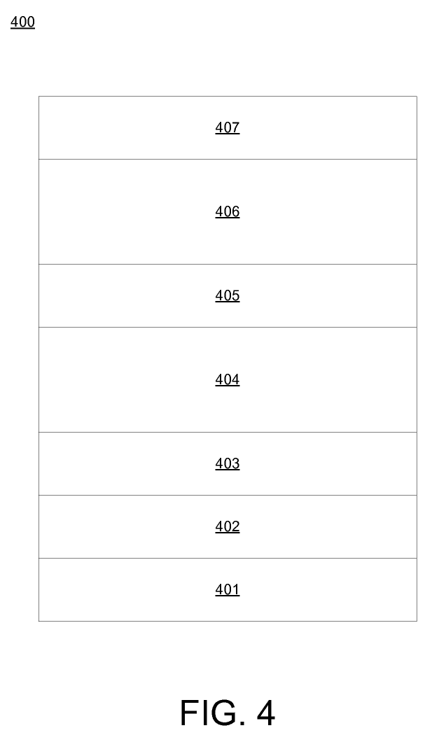

FIG. 4 illustrates an embodiment of a junction 400. Each of junctions 201-203 of FIG. 2 may comprise the series of layers 401-407 that are shown in junction 400. Contact 401 is formed at the bottom, and window layer 402 is formed on contact 401. Emitter 403 is formed on window layer 402. Base layer 404 is formed on emitter 403. Back surface field (BSF) 405 is formed on base layer 404. Back contact 406 is formed on BSF 405, and tunnel junction 407 is formed on back contact 406.

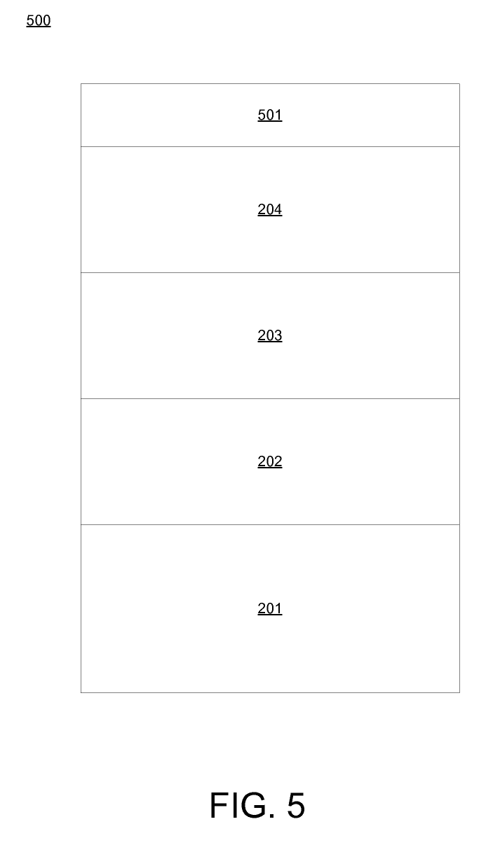

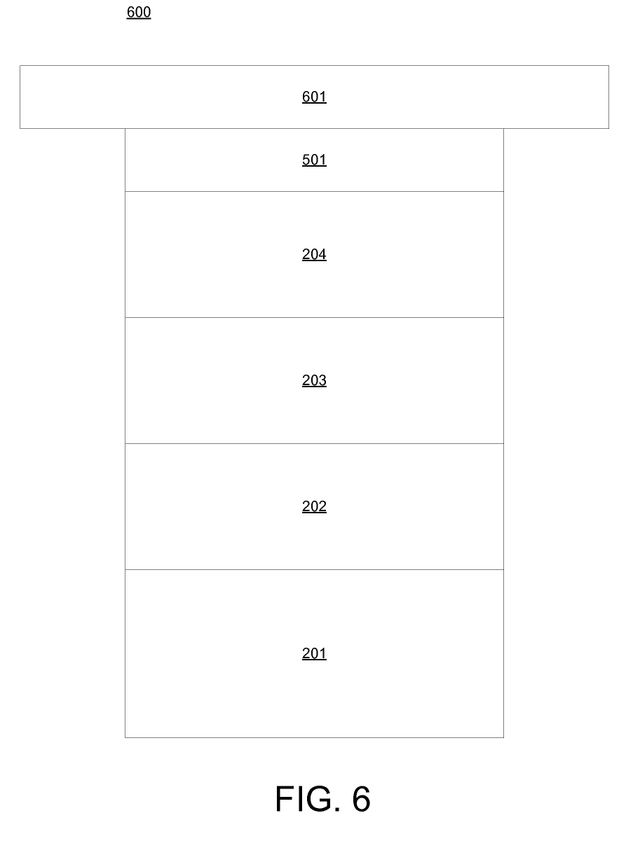

In block 102, a tensile stressed metal layer 501 is formed on junction 204, as is shown in FIG. 5. Metal layer 501 may comprise nickel (Ni), and may be about 5-6 microns thick in some embodiments. In block 103, a flexible substrate 601 is adhered to metal layer 501, as is shown in FIG. 6. Flexible substrate 601 may comprise polyimide (e.g, Kapton tape) in some embodiments.

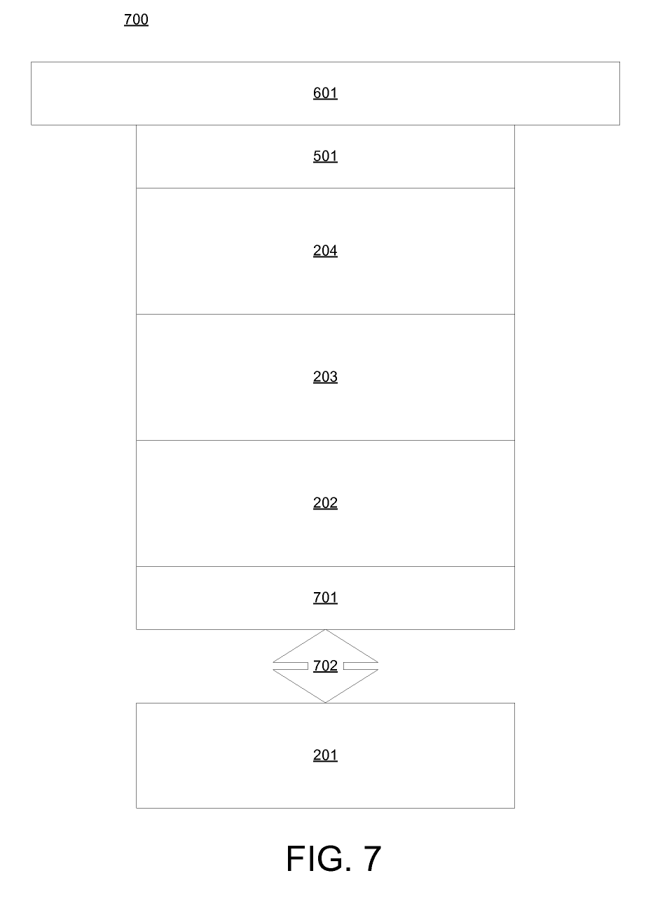

In block 104, spalling of junctions 202-204 is initiated, and a semiconductor layer 701 is separated from substrate 201 at fracture 702, as is shown in FIG. 7. Flexible substrate 601 may be used as a mechanical handle during spalling. The tensile stress in metal layer 501 encourages formation of fracture 702 in substrate 201. Semiconductor layer 701 may be less than about 10 microns thick in some embodiments. In some embodiments, a compressively strained cleave layer may be formed in substrate 201 to weaken the substrate 201 at a pre-determined physical depth or region before spalling, allowing precision in the location of fracture 702. The cleave layer may be formed by incorporating a layer into substrate 201 that is preferentially hydrogenated, or may comprise an interface layer having a lower melting point than substrate 201, such as germanium tin (GeSn). A temperature gradient (for example, a physical gradient or quenching) or etching may also be used to induce spalling of semiconductor layer 701 from substrate 201 at fracture 702.

In embodiments in which substrate 201 comprises the layers 301-305 shown in FIG. 3, fracture 702 may form in second seed layer 304, resulting in a top portion of second seed layer 304 forming semiconductor layer 701, and a bottom portion of second seed layer 304 remaining on etch stop/release layer 303. Etch stop layer 305 is located between semiconductor layer 701 and junction 202 in such embodiments. Etch stop layer 305 allows etching of semiconductor layer 701 without damaging junction 202. Etch stop/release layer 303 facilitates the return of the surface of substrate 201 to its original condition after spalling by allowing controlled removal of any remaining portion of layer 304 from substrate 201, so that substrate 201 may be reused as a new surface to fabricate additional PV cells.

Due to the tensile stress in metal layer 501, the semiconductor layer 701 and junctions 202-204 may possess residual compressive strain after spalling in some embodiments. The magnitude of the strain contained in semiconductor layer 701 and junctions 202-204 may be controlled by varying the thickness and/or stress of the metal layer 501, either before or after spalling. The optical properties of a PV cell built using semiconductor layer 701 and junctions 202-204 may be tuned by adjusting the amount of strain in semiconductor layer 701 and junctions 202-204.

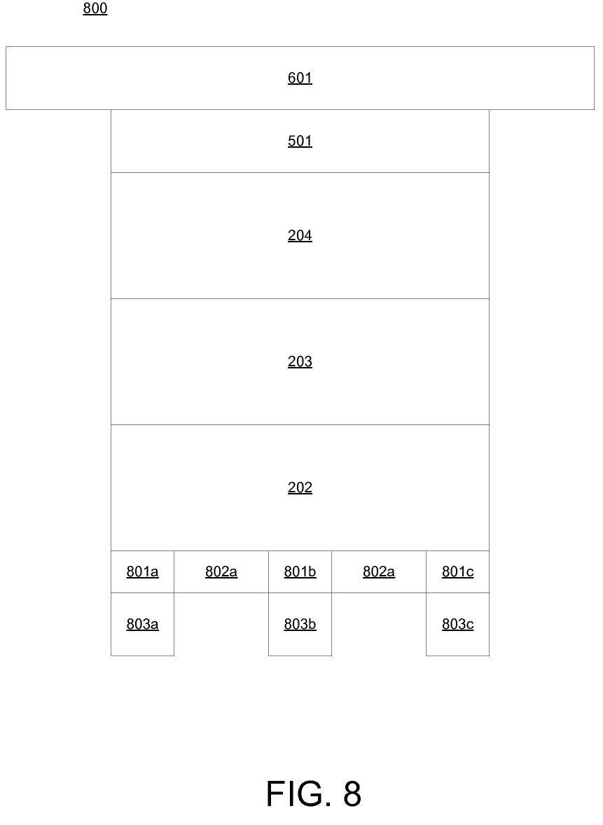

In block 105, multijunction PV cell 800 is formed, as is shown in FIG. 8. Portions of semiconductor layer 701 may be selectively removed by, for example, chemical or physical etching, to form semiconductor contacts 801a-c, which may be about 200-500 nanometers thick in some embodiments. An antireflective coating layer 802a-b, which may comprise an oxide- or nitride-based thin film, may then be formed over the exposed surface of junction 202. Metal electrodes 803a-c may then be formed on semiconductor contact 801a-c. Electrodes 803a-c comprise ohmic contacts to semiconductor contacts 801a-c. Electrodes 803a-c and semiconductor contacts 801a-c are shown for illustrative purposes only; a multijunction PV cell 800 may comprise any appropriate number of semiconductor contacts and electrodes. Metal layer 501 may function as a back metal contact for the multijunction PV cell 800. Flexible substrate 601 may allow electrical connection to metal layer 501, or flexible substrate 601 may be removed in some embodiments. Junctions 202-204 of multijunction PV cell 800 may total less than about 15 microns in thickness in some embodiments. Multijunction PV cell 800 may contain an amount of compressive strain induced in the semiconductor contacts 801a-c and junctions 202-204 by the stress in metal layer 501; the amount of strain in semiconductor contacts 801a-c and junctions 202-204 may determine the optical properties of multijunction PV cell 800.

The technical effects and benefits of exemplary embodiments include a relatively cost-effective method of fabricating a flexible, efficient multijunction PV cell.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment described in detail was chosen and described in order to best explain the principles of the invention and the practical application, and to enable others of ordinary skill in the art to understand the invention for various embodiments with various modifications as are suited to the particular use contemplated.

1. A method for fabrication of a multijunction photovoltaic (PV) cell, the method comprising:
forming a stack comprising a plurality of junctions on a substrate, each of the plurality of junctions having a respective bandgap, wherein the plurality of junctions are ordered from the junction having the largest bandgap being located on the substrate to the junction having the smallest bandgap being located on top of the stack;
forming a metal layer, the metal layer having a tensile stress, on top of the junction having the smallest bandgap;
adhering a flexible substrate to the metal layer; and
spalling a semiconductor layer from the substrate at a fracture in the substrate, wherein the fracture is formed in response to the tensile stress in the metal layer.

2. The method of claim 1, further comprising etching the semiconductor layer to form at least one semiconductor contact.

3. The method of claim 2, wherein the semiconductor contact layer is between about 200 nanometers and 500 nanometers thick.

4. The method of claim 2, further comprising forming an antireflective coating layer comprising an oxide- or nitride-based thin film on the junction having the largest bandgap.

5. The method of claim 2, further comprising forming at least one metal electrode on the at least one semiconductor contact, the at least one metal electrode comprising an ohmic contact to the at least one semiconductor contact.

6. The method of claim 1, wherein the metal layer comprises nickel.

7. The method of claim 1, wherein the substrate comprises one of gallium arsenide or germanium.

8. The method of claim 1, wherein the flexible substrate comprises polyimide.

9. The method of claim 1, wherein the metal layer comprises a back contact for the multijunction PV cell.

10. The method of claim 1, wherein the plurality of junctions comprises 3 junctions, and a thickness of the stack comprising the plurality of junctions is less than about 15 microns.

11. The method of claim 1, wherein the semiconductor layer is less than about 10 microns thick.

12. The method of claim 1, wherein one or more of the plurality of junctions is under a compressive strain, the compressive strain being induced by the tensile stress in the metal layer.

13. The method of claim 11, wherein the substrate comprises a seed layer located on a semiconductor substrate, an etch stop/release layer located on the seed layer, a second seed layer located on the etch stop/release layer, and an etch stop layer located on the second seed layer, wherein the junction having the largest bandgap is formed on the etch stop layer, and wherein the fracture is formed in the second seed layer.

14. The method of claim 1, wherein each of the plurality of junctions comprises: a contact layer, a window layer located on the contact layer, an emitter located on the window layer, a base layer located on the emitter, a back surface field located on the base layer, a back contact located on the back surface field, and a tunnel junction located on the back contact.

15. The method of claim 1, further comprising forming a cleave layer in the substrate, the cleave layer configured to determine the location of the fracture.

16. The method of claim 15, wherein the cleave layer comprises one of germanium tin (GeSn), a hydrogenated layer, or interface layer within the substrate.

17. A multijunction photovoltaic (PV) cell, comprising:
at least one semiconductor contact;
a stack comprising a plurality of junctions, each of the plurality of junctions having a respective bandgap, wherein the plurality of junctions are ordered from the junction having the largest bandgap being located on the at least one semiconductor contact to the junction having the smallest bandgap being located on top of the stack;
a metal layer having a tensile stress located on top of the junction having the smallest bandgap, the metal layer comprising a back contact; and
a flexible substrate adhered to the metal layer.

18. The multijunction PV cell of claim 17, wherein the semiconductor contact is between about 200 nanometers and 500 nanometers thick, and comprises one of germanium or gallium arsenide; wherein the flexible substrate comprises polyimide; and wherein the metal layer comprises nickel.

19. The multijunction PV cell of claim 17, further comprising an antireflective coating layer comprising an oxide- or nitride-based thin film on the junction having the largest bandgap, and at least one metal electrode on the at least one semiconductor contact, the at least one metal electrode comprising an ohmic contact to the at least one semiconductor contact.

20. The multijunction PV cell of claim 17, wherein one or more of the plurality of junctions is under a compressive strain, the compressive strain being induced by the tensile stress in the metal layer.
